(19) United States
(12) Patent Application Publication
(10) Pub. No.: US 2004/0091750 A1
(43) Pub. Date: May 13, 2004

(54) Coating for a handle

(76) Inventors: Kayser Oliver, Lohmar/Neuhonrath (DE); Eugen Eibofner, Biberach (DE); Bernhard Lingenhole, Warthausen (DE)

Correspondence Address: Marshall Gerstein & Borun, 6300 Sears Tower, 233 South Wacker Drive, Chicago, IL, 60606-6402, US

(21) Appl. No.: 10/472,004

(22) PCT Filed: Mar. 26, 2002
(86) PCT No.: PCT/EP02/03392

(30) Foreign Application Priority Data
Mar. 26, 2001 (DE) 101 14 657.4

(51) Int. Cl. C23C 16/22; B32B 9/00

(52) U.S. Cl. 428/698; 427/255.394

(57) ABSTRACT

A coating for a handpiece (1) for dental-medical or surgical purposes consists of a hard material layer (11) having a predetermined roughness and of a plastics layer (12), having a reduced wettability, arranged on the hard material layer (11). Through this there is obtained a dirt repellent surface. At the same time handling is improved, since a slipping of the handpiece is avoided.

The present invention relates to a coating for a handpiece for medical, dental-medical or surgical purposes or a handpiece with this coating or a method for the coating of the surface of such a handpiece.

The surface properties of dental-medical or surgical handpieces are attributed a particular significance. Since the beginning of handpiece technology it has been striven to so configure the surfaces of the handpieces that they are on the one hand, for reasons of hygiene, dirt repellant and on the other hand that a slipping in the fingers of a user is avoided, in particular even when the handpieces are moist.

A known solution, with which this desire is taken into account, consisted in providing the surface of the handpiece with honeycomb-like facets. Through this the handpiece surface has a profile which offers a certain hold, through which correspondingly handling is improved. However, with this solution, there cannot be realised a surface which is completely dirt repellant, since as before dirt can attach to the facets.

A further known solution in the case of a dental handpiece consisted in that there were provided in the middle grip region so-called knurled rings. However, even these knurled rings tend to take up dirt. In a further development, therefore, the surface in the middle region of the handpiece was configured to be wave-like and at the same time the surface was roughened.

It can be understood from the above-indicated examples that in the configuration of the handpieces a compromise must always be made between on the one hand a surface which is as smooth as possible and on the other hand a surface which is as rough as possible. The smoother is the surface, the lesser is the tendency to take up dirt. On the other hand, through a rough surface handling is facilitated and the danger of the handpiece slipping during its employment reduced.

It is thus the object of the present invention to indicate a further possibility for the configuration of the surface of a handpiece for dental-medical or surgical purposes, through which on the one hand the tendency to take up dirt or liquids, in particular water, is reduced and which on the other hand makes possible an optimal handling of the handpiece.

This object is achieved by means of a coating for a handpiece which has the features of claim 1.

The coating in accordance with the invention is comprised of a hard material layer, which exhibits a predetermined roughness, and of a plastics layer having a reduced wettability applied on the hard material layer. The hard material layer serves first the purpose of protecting the handpiece surface from external influences, in particular of a mechanical kind. By means of its predetermined roughness there is ensured a secure handling of the handpiece even in the moist condition. The plastics layer applied on the hard material layer lends the coating dirt repellent properties. In comparison to the surface deformations predetermined through the roughness of the hard material layer, the thickness of the plastics material layer is however only very slight, so that the roughness originally attained by means of the hard material layer is only insignificantly reduced through the additional coating. Preferably the hard material layer has an averaged roughness depth Rz of ca. 2-12 μm—in particular of 4-8 μm—and an arithmetical mean roughness value Ra of ca. 2-1.2 μm. Ideally, roughness values of Rz ca. 5-6 μm and Ra ca. 0.2-0.5 μm are attained. Thereby the hard material layer is preferably of chromium nitride (CrN). The plastics layer may be formed for example by means of a fluorine containing plastics, in particular polytetrafluoroethylene (PTFE), also known under the name Teflon.

The wettability of the plastics layer is reduced with reference to the wettability of the smooth surface of a handpiece of steel. Although handpieces of plastics have been known, there was employed for this purpose however, polyetheretherketone (PEEK). This plastics does not exhibit reduced wettability. For a plastics layer with reduced wettability there are suited non-polar plastics. The wettability of the plastics layer of a non-polar plastics is significantly reduced with reference to the wettability of steel and polyetheretherketone (PEEK).

In accordance with a further aspect of the present invention there is indicated a method for the coating of the surface of a grip region of a dental or surgical handpiece, which is comprised of a plurality of steps. In a first step there is applied a hard material layer having a predetermined roughness to the handpiece surface and in a following step the hard material layer is sealed with a plastics layer having a reduced wettability.

The application of the hard material layer is effected preferably by means of a vacuum coating process, in particular by means of a so-called PVD—(physical vapour deposition—physical deposition from the gas phase) process. For this purpose, the substrate is arranged within a vacuum chamber. For the application of a chromium nitride layer for example, chromium is then evaporated within the chamber and at the same time nitrogen in a suitable quantity is supplied to the chamber. The application is effected preferably at a total pressure which is increased in comparison with usual PVD coating processes, at which total pressure the desired roughness for the hard material layer is attained, for example at a pressure of ca. 0.8-5.0×10⁻² mbar.

In accordance with an advantageous further development of the present invention, in a last phase of the application of the hard material layer the nitrogen introduced into the chamber is replaced to a certain extent by an inert gas, for example by argon or another noble gas. Through this, the upper regions of the hard material layer manifest a slightly altered chemical make-up, which has the consequence that a certain, grey-blue colour tone is attained. Preferably the partial replacement of the nitrogen by the inert gas is effected during the application of the overall, or of the last 400 nm of the, hard material layer.

The sealing of the hard material layer with the plastics layer is effected preferably by means of a wet chemical reaction. After the application of the plastics layer this is baked in at about 260° C.

The coating in accordance with the invention represents an optimal compromise between a surface which is as rough as possible, which ensures a good handling of the handpiece, and a surface which is as smooth as possible and thus dirt repellant. Further, there is attained an optimal protection of the handpiece from external influences, of mechanical and also chemical type.

The invention relates also to a medical or dental-medical or surgical handpiece having the coating in accordance with the invention. The advantages described above apply also for such a handpiece in accordance with the invention. Thereby, the handpiece may extend straight or curved in an arc shape or may be angled, as is per se usual. The coating in accordance with the invention and the method of coating in accordance with the invention are well suited for these forms of the handpiece.

In the following the invention will be described in more detail with reference to the accompanying drawings. There is shown:

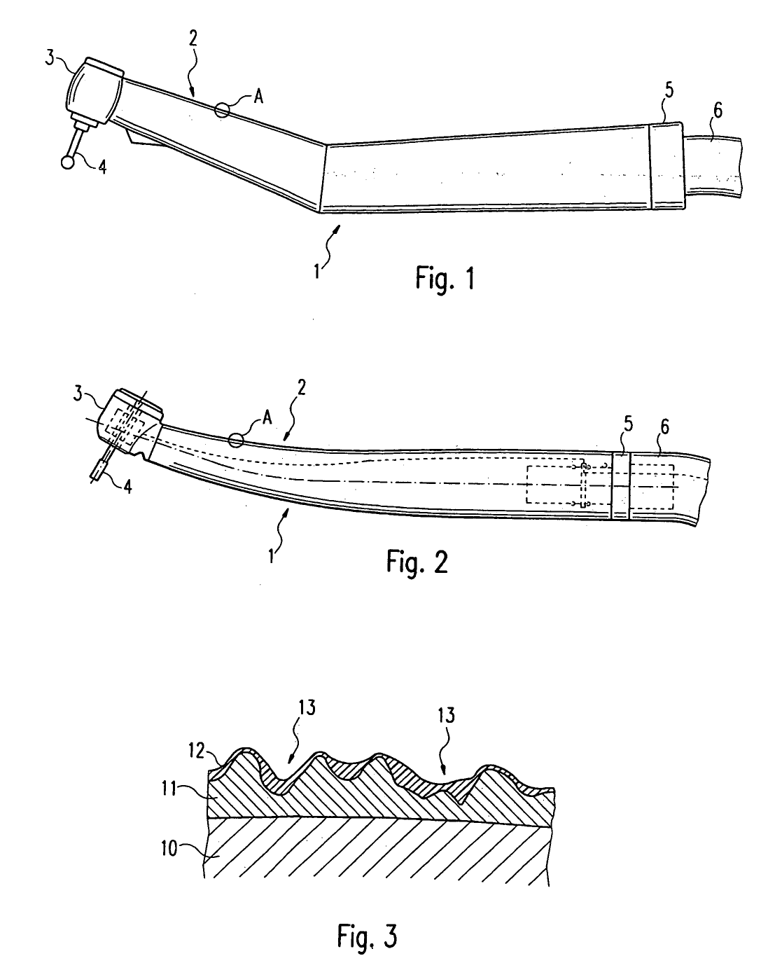

FIG. 1 a dental-medical handpiece in a general form,

FIG. 2 a handpiece in a modified form, and

FIG. 3 an illustration of the coating in accordance with the invention, to an enlarged scale, in section.

The handpiece 1 illustrated in FIGS. 1 and 2 is a dental handpiece, e.g. a drill handpiece. Of course, the coating in accordance with the invention can be put to use also with all other dental or surgical handpieces. The illustrated handpiece 1 consists of an elongate grip sleeve, which is slightly angled (FIG. 1) or may be curved in an arc shape (FIG. 3). At the forward end there is located a head housing 3, within which a non-illustrated drive device for driving a dental tool—in the present example for driving a drill 4—is arranged. At its rearward end, the handpiece 1 is connected via a coupling piece 5 rotatably with a supply hose 6 for the delivery of supply and treatment media, light or electrical energy. The tool can be mounted in a holder device which is arranged at the forward end of the handpiece 1.

For use, the handpiece 1 is held by a user at its forward grip region 2. At least this forward grip region 2 manifests the coating in accordance with the invention. It would, however, also be conceivable that the entire surface of the handpiece 1 is provided with this coating.

Before the production of the coating in accordance with the invention is described, its structural make-up will first be explained with reference to FIG. 3. FIG. 3 thereby shows a detail A of the handpiece surface in an illustration to an enlarged scale, in section. The surface of the handpiece is itself designated with the reference sign 10, the coating in accordance with the invention is comprised of the two layers 11 and 12 arranged thereabove.

The surface structure of the coating in accordance with the invention is determined by means of the hard material layer 11 applied to the handpiece surface 10, which in the present case is a chromium nitride (CrN) layer. Due to its extremely great hardness this material frequently finds employment in the printing or stamping technology or serves for protection for tools exposed to corrosion, and as a decorative layer.

In comparison to usual chromium nitride coatings, or also other hard material layers, the illustrated hard material layer 11 has in accordance with the invention however, a significantly higher roughness. For the characterisation of the roughness of a surface typically two parameters are determined, on the one hand the averaged roughness depth Rz and on the other hand the arithmetical mean roughness value Ra. Thereby there is involved in the case of the averaged roughness depth Rz the arithmetic mean of the greatest individual roughness depths of a plurality of individual measurement paths bordering on one another. In contrast the more commonly used arithmetical mean roughness value Ra is the arithmetical mean value of the absolute values of the profile deviations within a predetermined reference path. This value is in principle smaller than the value determined for the averaged roughness depth Rz determined for the same roughness profile. The hard material layer 11 illustrated in FIG. 3 has preferably an averaged roughness depth Rz of about 2-12 μm—particularly preferred about 4-8 μm, and ideally from 5-6 μm—and an arithmetical mean roughness value Ra of about 0.2-1.0 μm or preferably about 0.2-0.5 μm. There is thus involved not a smooth structure but a structure provided with a multiplicity of pores 13, which ensures a particularly good handling of the handpiece, even in the presence of moisture.

The plastic sealing 12 is applied to the upper side of the hard material layer 11, which sealing lends the coating in accordance with the invention the second property which is striven for, namely to be as dirt repellant or liquid repellent or water repellent as possible. The plastics layer 12, which is preferably a polytetrafluoroethylene layer or another fluorine-containing plastics, is only very thin in comparison to the surface deformations predetermined by the pores 13 of the hard material layer 11 and thus compensates for the roughness of the hard material layer 11 only to a very slight degree, so that the slippage-free handling of the handpiece is not affected. Both the hard material layer 11 and also the plastics layer 12 further contribute to protecting the handpiece from external influences. The hard material layer 11 thereby serves in particular the mechanical protection of the handpiece, while the plastics sealing 12 reduces chemical influences.

In the following, the method in accordance with the invention for the application of the coating will be explained. The lower hard material layer is thereby applied by means of a vacuum coating process, in the present case by means of a so-called PVD (physical vapour deposition) process. Thereby metallic starting materials are, through the addition of thermal energy, taken from a solid phase into the gas phase, ionised and accelerated towards the substrate. The coating process thereby takes place in an evacuated vacuum chamber, whereby through the controlled addition of further components in the form of reactive gases the desired hard material layer is attained.

The methods and apparatuses for carrying such vacuum coatings are already sufficiently well known, for example from DE 41 25 365 C1. In the following, therefore, the process will merely be summarised and the special features for the attainment of the desired roughness explained.

The coating is effected preferably in accordance with a so-called arc vaporisation (arc-coating) at a reduced total pressure in a gas-tight vacuum chamber. The erosion is thereby effected from metallic donor rounds by means of surface-bound arcs. The donor rounds are mounted in advance in the vacuum chamber, electrically insulated and biassed with ca. 30 volts negative with respect to the potential of the chamber wall. Due to the high energy of the arcs the donor material present in solid form is locally evaporated and ionised. Via a negative voltage the ions are then accelerated towards the substrate.

For the application of the chromium nitride layer, pure chromium is used as donor material. By means of the additional introduction of pure nitrogen into the vacuum chamber the chromium irons are supplemented on the handpiece surface to be coated to chromium nitride CrN. With the aid of a mass flow regulator balanced with the suction power of the vacuum pumps the quantity of the introduced nitrogen can thereby be so set that there is provided in the coating chamber a total pressure of ca. 0.8-5.0×10⁻² mbar.

The above-indicated pressure value is higher than the pressure conventionally present upon deposition of hard material layers. Through this, the desired surface structure with a significantly greater roughness than usual is attained. In order to lend the hard material layer vapour deposited on the handpiece a particular colour, during the application of the overall or the last 400 nm, the nitrogen atmosphere present in the vacuum chamber is thereby diluted through the addition of argon. Through this, the upper regions of the hard material layer manifest a slightly altered chemical make-up, through which typically a grey-blue colour tone arises. Instead of argon they may however be employed also another noble gas or inert gas.

The advantage of the indicated PVD-ARC process lies in that the layers can be deposited even at a relatively low coating temperature of less than 200° C. Preferably thereby, as a preliminary to the coating, the substrate surface is additionally cleaned by means of a plasma cleaning process.

The subsequent application of the Teflon layer is effected by means of a wet chemical process in air atmosphere. Subsequently, the sealing is baked in at ca. 260° C. Alternatively to this, however, the plastics sealing can be applied also by means of plasma polymerisation, i.e. by means of a thin layer technique.

The indicated method is thus based on the already present basic knowledge of the coating of workpieces and differs from the known PVD processes primarily in that through the selection of a higher pressure value the desired roughness is attained and on the other hand through the partial replacement of the nitrogen by argon the hard material layer is lent a particular colour. At the same time the coating in accordance with the invention lends the handpiece excellent characteristics, through which on the one hand handling is improved and on the other hand the tendency to take up dirt is reduced. These characteristics, which actually contradict one another, are attained in particular by means of the combination in accordance with the invention of a rough hard material layer with a dirt repellant plastics sealing.

1. Coating for a handpiece (1) for dental-medical or surgical purposes, comprised of a hard material layer (11) having a predetermined roughness and of a plastics layer (12), having a reduced wettability, arranged on the hard material layer (11).

2. Coating according to claim 1,
characterised in that,
the hard material layer (11) is of chromium nitride (CrN).

3. Coating according to claim 1 or 2,
characterised in that,
the hard material layer (11) manifests in substance a roughness with Rz=2-12 μm and Ra=0.2 to 1.0 μm.

4. Coating according to claim 3,
characterised in that,
the hard material layer (11) manifests in substance a roughness with Rz=4-8 μm and Ra=0.2 to 1.0 μm.

5. Coating according to claim 4,
characterised in that,
the hard material layer (11) manifests in substance a roughness with Rz=5-6 μm and Ra=0.2 to 0.5 μm.

6. Coating according to any preceding claim,
characterised in that,
the plastics layer (12) is formed by means of a fluorine-containing plastics.

7. Coating according to claim 6,
characterised in that,
the plastics layer (12) is a polytetrafluoroethylene layer.

8. Handpiece (1) for dental-medical or surgical purposes, which has in a grip region (2) a coating in accordance with any preceding claim.

9. Method for coating the surface of a grip region (2) of a handpiece (1) for dental-medical or surgical purposes, with the following steps:
a) applying to the handpiece surface a hard material layer (11) with a predetermined roughness and
b) sealing the hard material layer (11) with a plastics layer (12) having a reduced wettability.

10. Method according to claim 9,
characterised in that,
the hard material layer (11) is of chromium nitride (CrN).

11. Method according to claim 9 or 10,
characterised in that,
in step a) the hard material layer (11) is applied by means of a vacuum coating process.

12. Method according to claim 10 and 11,
characterised in that,
for the application of the hard material layer (11) the handpiece (1) is arranged in a vacuum chamber, whereby for the coating, chromium is evaporated and at the same time nitrogen is supplied into the chamber.

13. Method according to claim 12,
characterised in that,
the coating is effected at a total pressure of ca. 0.8-5.0×10⁻² mbar.

14. Method according to claim 12 or 13,
characterised in that,
during a final phase of the coating, the nitrogen introduced into the chamber is partially replaced by an inert gas.

15. Method according to claim 14,
characterised in that,
argon is employed as inert gas.

16. Method according to claim 14 or 15,
characterised in that,
the replacement of the nitrogen by the inert gas is effected during the vapour deposition of the last 400 nm of the hard material layer (11).

17. Method according to any of claims 9 to 16,
characterised in that,
the hard material layer (11) manifests in substance a roughness with Rz=2-12 μm and Ra=0.2-1.0 μm.

18. Method according to claim 17,
characterised in that,
the hard material layer (11) manifests in substance a roughness with Rz=4-8 μm and Ra=0.2-1.0 μm.

19. Method according to claim 18,
characterised in that,
the hard material layer (11) manifests in substance a roughness with Rz=5-6 μm and Ra=0.2-0.5 μm.

20. Method according to any of claims 9 to 19,
characterised in that,
in step b) the plastics layer (12) is applied by means of a wet chemical reaction.

21. Method according to any of claims 9 to 19,
characterised in that,
in step b) the plastics layer (12) is applied by means of plasma polymerisation.

22. Method according to claim 20 or 21,
characterised in that,
after the application of the plastics layer (12) this is baked in at about 260° C.

23. Method according to any of claims 9 to 22,
characterised in that,
in step b) there is applied a fluorine-containing plastics layer.

24. Method according to claim 22,
characterised in that,
in step b) there is applied a polytetrafluoroethylene layer.

25. Medical or dental-medical handpiece (1) having an elongate grip sleeve with a grip region (2), which has at its rearward end a coupling piece (5) with which it can be connected with a supply hose (6), and at its forward end has a holder device for a tool,
characterised in that,
the handpiece (1) has at least in its grip region a coating in accordance with one or more of claims 1 to 8.
